(19) United States
(12) Patent Application Publication
(10) Pub. No.: US 2009/0260564 A1
(43) Pub. Date: Oct. 22, 2009

(54) Method for growing silicon single crystal

(76) Inventors: Yasuhiro SAITO, Tokyo (JP); Nobumitsu TAKASE, Tokyo (JP)

Correspondence Address: CLARK & BRODY, 1090 VERMONT AVENUE, NW, SUITE 250, WASHINGTON, DC, 20005, US

(21) Appl. No.: 12/385,730

(22) Filed: Apr. 17, 2009

(30) Foreign Application Priority Data
Apr. 21, 2008 (JP) 2008-110515

(51) Int. Cl. C30B 15/00

(52) U.S. Cl. 117/35

(57) ABSTRACT

A method for growing silicon single crystal by the CZ method, namely by feeding silicon materials for crystal into a crucible to melt the materials, and growing a silicon single crystal on the lower end of the seed crystal, comprises: forming a narrowingly tapered portion with a gradually decreased seed crystal diameter by pulling up the seed crystal inserted in the melt; and providing increased or decreased neck diameter regions in the process of forming a neck in such a manner that each increased neck diameter is provided by increasing the neck diameter, followed by reverting the neck diameter to the original diameter, or alternatively, each decreased neck diameter region is provided by decreasing the neck diameter, followed by reverting the diameter to the original diameter, thereby enabling to reliably eliminate dislocations remaining in the central axial region of the neck in the step of necking. When the neck diameter is increased or decreased at the final stage in the process of forming the neck, dislocations can be eliminated more efficiently.

### BACKGROUND OF THE INVENTION

1. Field of the Invention

The present invention relates to a method for growing a silicon single crystal by the Czochralski method (hereinafter referred to as “CZ method”) and, more particularly, to a method for growing a silicon single crystal by which dislocations existing in the central axial region of a neck can be reliably eliminated even when a neck diameter is large on the occasion of seed narrowing in growing a silicon single crystal large in diameter and heavy in weight.

2. Description of the Related Art

Various methods are available for the production of silicon single crystal to be used as semiconductor substrates; among them, the CZ method is widely employed.

FIG. 1A and FIG. 1B are schematic views of an essential constitution of a crystal pulling apparatus suited for pulling up a silicon single crystal by the CZ method. FIG. 1A is an overall view and FIG. 1B is a partial enlarged view (the portion surrounded by the broken-line circle in FIG. 1A).

As shown in FIG. 1A, the exterior of the pulling apparatus is formed by a chamber (not shown), and a crucible 1 is disposed in the middle thereof. This crucible 1 has a double-wall structure in which an inner structural vessel la is made of quartz in the form of a bottomed cylinder (hereinafter referred to as “quartz crucible”) and an outer structural vessel 1b made of graphite in the form of a bottomed cylinder fits onto the outside of and braces the quartz crucible la (hereinafter referred to as “graphite crucible”).

The crucible 1 is fixedly mounted to the upper end of a supporting shaft 6, while being allowed to rotate and ascend or descend. And a resistance heating type heater 2 is disposed generally coaxially around the crucible 1. A predetermined weight of silicon materials for semiconductors fed into the crucible 1 are melted to form a melt 3.

A pull shaft 5 (or wire; hereinafter collectively referred to as “pull shaft”), which rotates on the same axis with the supporting shaft 6 at a predetermined speed either in the reverse direction or the same direction relative to the rotating direction of the supporting shaft 6, is coaxially disposed above the crucible 1 containing the melt 3, and a seed crystal 7 is held at the lower end of the pull shaft 5.

On the occasion of pulling up a silicon single crystal using such a pulling apparatus, materials for a semiconductor silicon single crystal are fed into the quartz crucible la and melted by means of the heater 2 disposed around the crucible 1 in an inert gas atmosphere at a reduced pressure to yield the melt 3, the seed crystal 7 held at the lower end of the pull shaft 5 is immersed into the surface layer of the melt 3, and the pull shaft 5 is pulled up for growing a single crystal on the lower end face of the seed crystal 7 while the crucible 1 and the pull shaft 5 are rotated.

On that occasion, after a necking process (step) as decreasing the diameter of the seed crystal 7 by adjusting the pull rate to form a narrowingly tapered portion 8 and a neck 9, the pull rate is lowered to increase the crystal diameter gradually to form a shoulder 10, followed by pulling up a constant diameter region 11 as shown in FIG. 1B. After the constant diameter region arriving at a predetermined length, the crystal diameter is gradually decreased, and the bottom end of the crystal is separated from the melt 3, thus one pulling campaign ends to obtain a silicon single crystal 4 having a predetermined shape.

The above-mentioned necking (this step is also referred to as “seed narrowing”) is an essential step for eliminating high-density dislocations introduced into the seed crystal due to heat shock upon contact of the seed crystal with the silicon melt. This method of eliminating dislocations is called the Dash's method.

Various techniques have so far been proposed for the elimination of dislocations introduced into the seed crystal on the occasion of pulling up a silicon single crystal. For example, Japanese Patent No. 2822904 discloses a method for producing silicon single crystal in which a seed crystal is pulled up while maintaining the length of the tapered narrowed portion subsequent to the seed crystal to be 2.5 to 15 times the diameter of the seed crystal, maintaining the diameter of a generally cylindrical narrowed portion following the tapered narrowed portion to be 9% to 90% of the diameter of the seed crystal, maintaining the range of fluctuation of diameter of the generally cylindrical narrowed portion within 1 mm and the length of thereof within the range of 200 mm to 600 mm. Thus, it is alleged that even when the diameter of the seed narrowing portion is made large, dislocations can be eliminated with a specific shape from the lower end of the seed crystal to the lower end of the generally cylindrical narrowed portion.

Japanese Patent Application Publication No. 10-72279 discloses a method and an apparatus, comprising: forming an enlarged portion with an enlarged crystal diameter below a neck, then forming a narrowed portion with a narrowed diameter, and pulling up a single crystal while holding the narrowed potion with a single crystal holding means for pulling up a single crystal with a large diameter of 12 inches or more and heavy weight. Allegedly, this pulling method makes it possible to pull up a large-sized single crystal with ease without causing such an accident as damaging or falling and further makes it possible to readily adapt to the changes in melt temperature and other conditions and prevent the introduction of dislocations into the narrowed portion, since the diameter is controlled by constantly measuring the luminance of the single crystal growth interface (meniscus) by means of an optical measuring means during the formation of the narrowed portion,.

To cope with demands for further integration of semiconductor devices in recent years as well as for cost reduction and productivity enhancement, wafers with a larger diameter are sought after and therefore, the grown silicon single crystal is increasing in diameter; it is thus urgent to develop a technology enabling the production of large-diameter, dislocation-free silicon single crystal.

In this regard, when a narrow neck having a diameter of about 3 mm is formed by the Dash's method, dislocations can be eliminated. However, when the neck diameter is 4 mm or larger, dislocations remaining in the central axial region of the neck hardly move to the periphery and, even when the neck length is increased, a few dislocations may still remain in the central axial region of the neck. It has been found that, in such a case, there arises a problem; namely the dislocations are inherited by the crystal grown through the neck, resulting in failure to grow a dislocation-free silicon single crystal.

Neither of the above-cited Japanese Patent No. 2822904 and Japanese Patent Application Publication No. 10-72279 describe the elimination of such a few dislocations possibly remaining in the central axial region even after seed narrowing.

### SUMMARY OF THE INVENTION

The present invention is made in view of the above problems during pulling up a silicon single crystal. It is an object of the present invention to provide a method for growing a silicon single crystal by which dislocations remaining in the central axial region of the neck can reliably be eliminated on the occasion of producing a heavy and large-diameter silicon single crystal, in particular.

For accomplishing the above object, the present inventors first carried out the treatment by the conventional Dash's method to eliminate dislocations introduced into the seed crystal immersed in the silicon melt to thereby examine the state of elimination of dislocations in the neck.

FIGS. 2 show X ray topography (XRT) photos showing examples of the state of elimination of dislocations in the neck formed by the conventional Dash's method, when seed crystals having crystal orientation [100] are immersed in the silicon melt and subjected to seed narrowing. In these photos, each white portion indicates the portion where there are dislocations. In FIGS. 2, the direction of pulling is in the direction toward the left side for convenience sake.

In FIGS. 2, the site “contact with melt” indicates the position of immersion of each seed crystal into the silicon melt; seed narrowing was performed by pulling up the seed crystal from that site. The “pull length until dislocations free” as shown in the view, namely the length from the “contact with melt” site to the outlined arrow (an arrow marked with DF (Dislocation Free) in FIG. 2C), is the pull length judged as dislocations are freed in XRT testing.

Dislocations were eliminated/freed at a pull length shorter than 100 mm in FIGS. 2A and 2B, and dislocations were eliminated/freed at a pull length of 115 mm in FIG. 2C. Namely, dislocations were eliminated/freed at a seed crystal pull length of about 100 mm in the observation by XRT testing. However, dislocations not shown in FIGS. 2 often remain in the central axial region (center and its close vicinity thereof) of the neck in parallel to the central axis of the neck (such dislocations are referred to herein as “on-axis dislocations). Skilled persons can discriminate such on-axis dislocations by observing the state of the axis.

In the course of investigations for a method for completely eliminating dislocations remaining in the central axial region of the neck (on-axis dislocations) after the dislocation elimination by the Dash's method, the present inventors found that the dislocation density can be decreased by slightly decreasing the neck diameter (within about 1 mm).

FIG. 3 is an X ray topography (XRT) photo showing an example of how dislocation-free can be attained in the neck by decreasing the neck diameter, as shown in contrast with a schematic view of the decrease of the dislocation density.

In this example, a seed crystal having crystal orientation [100] was immersed in the silicon melt, and the pull rate was immediately increased slightly so as to the pull rate slightly to decrease the neck diameter slightly. And then, restoring the original diameter, pulling was continued. The extent of diameter reduction was about 1 mm, as recognized in comparison with a scale of the diameter of 8 mm shown in the photo.

As shown in FIG. 3, the dislocation density rapidly decreased simultaneously with the neck diameter reduction, resulting in dislocation-free. Further, there were noon-axis dislocations from the observation of the state of the axis after pulling completely from the silicon melt. Such dislocation freeing as a result of neck diameter reduction and such a observation result of the axis state were found not only in the example shown in FIG. 3 but also in pulling of other seed crystal. Therefore, this dislocation elimination by neck diameter reduction is considered to be effective also in eliminating on-axis dislocations.

The present invention is completed based on such findings, the gist of the invention consists in a method for growing silicon single crystal as defined below.

Namely, the present invention is directed to a method for growing a silicon single crystal by the Czochralski method, namely by charging silicon raw materials for crystal into a crucible to melt the materials, and pulling up a seed crystal immersed into the melt while rotating the seed crystal to thereby grow a silicon single crystal on the lower end of the seed crystal, the method comprising: forming a narrowingly tapered portion with a gradually decreased seed crystal diameter by pulling up the seed crystal immersed in the melt; and providing an increased or a decreased neck diameter region in the process of forming a neck with a constant nominal diameter in such a manner that the increased neck diameter region is provided by increasing the neck diameter, followed by decreasing the diameter, or alternatively, the decreasing neck diameter region is provided by decreasing the neck diameter, followed by increasing the diameter.

The “narrowingly tapered portion” and “neck” respectively indicate a narrowingly tapered portion 8 and a neck 9 as shown in the enlarged view in FIG. 1. In the following, the term“neck portion” is used to refer to both the narrowingly tapered portion and neck collectively. “Seed narrowing” means the step of necking in which the narrowingly tapered portion and the neck are formed by decreasing the seed crystal diameter. The term “seed narrowing length” is the height difference in pulling the seed crystal when performing the seed narrowing, also refers to the length of the neck portion (narrowingly tapered portion and neck) from the lower end of the seed crystal.

In the method for growing a silicon single crystal according to the present invention, if the neck diameter is increased or decreased at the final stage in the process of forming the neck, all dislocations including on-axis dislocations can be eliminated more efficiently.

Further, in the method for growing a silicon single crystal according to the present invention, if a plurality of the increased diameter regions or decreased diameter regions are formed, it is very effective in enhancing the dislocation eliminating effect.

By the method for growing a silicon single crystal according to the present invention, it is possible to reliably eliminate those dislocations remaining in the central axial region in the neck (on-axis dislocations) in a simple and easy way even in the case where the narrowingly tapered portion in seed narrowing is not allowed to be smaller because of growing the heavy silicon single crystal with large diameter. Therefore, absolutely dislocation-free silicon single crystal can be grown in a stable manner.

### BRIEF DESCRIPTION OF THE DRAWINGS

FIG. 1A and FIG. 1B are schematic views of an essential configuration of a crystal pulling apparatus suited for pulling up a silicon single crystal by the CZ method. FIG. 1A is an overall view and FIG. 1B is an enlarged view of a part thereof;

FIGS. 2 are XRT photos showing examples of the state of elimination of dislocations in the neck by the conventional Dash's method;

FIG. 3 is an XRT photo showing an example of how dislocation-free can be attained in the neck by decreasing the neck diameter, as shown in contrast with a schematic view of the decrease of the dislocation density;

FIG. 4 is a schematic view of the state of forming decreased diameter regions in the neck in the process of forming the neck after forming a narrowingly tapered portion in carrying out the method for growing the silicon single crystal according to the present invention;

FIG. 5 is a view showing the process of forming a neck portion (narrowingly tapered portion and neck) to be carried out in the method for growing a silicon single crystal according to the present invention in step order.

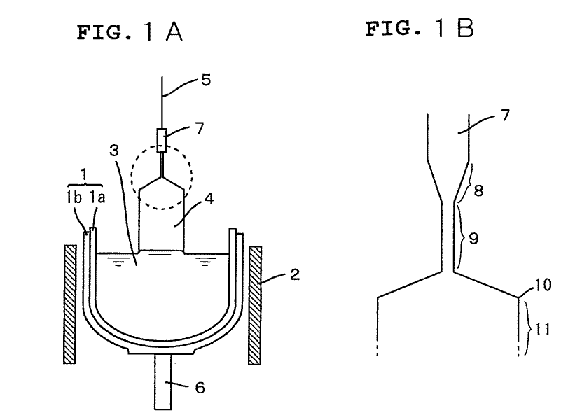

### DETAILED DESCRIPTION OF THE PREFERRED EMBODIMENTS

The method for growing a silicon single crystal according to the present invention is a method for growing a silicon single crystal using the CZ method, comprising: forming a narrowingly tapered portion with a gradually decreased seed crystal diameter by pulling up the seed crystal immersed in the melt; and providing an increased or a decreased neck diameter region in the process of forming the neck with a constant nominal diameter (namely substantially cylindrical) in such a manner that the increased neck diameter region is provided by increasing the neck diameter, followed by decreasing the diameter (namely, convex region), or alternatively, the decreased neck diameter region is provided by decreasing the neck diameter, followed by increasing the diameter (concave region).

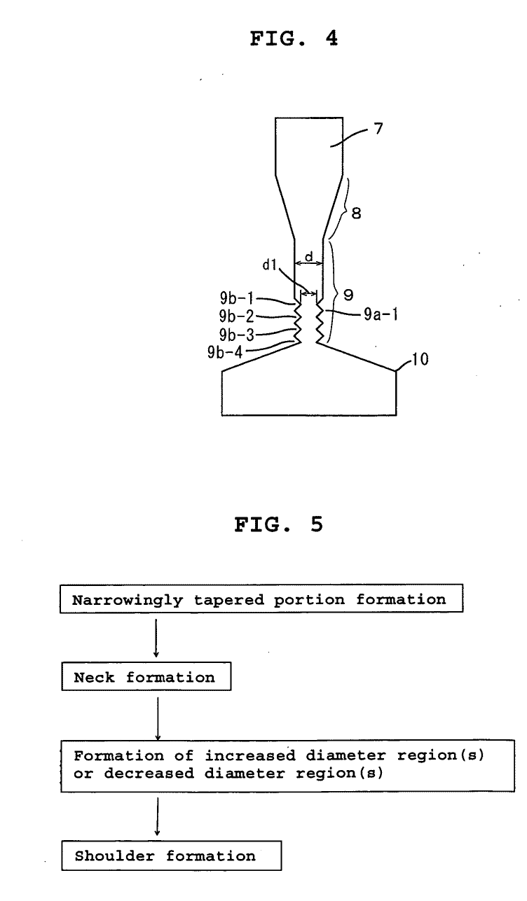

FIG. 4 is a schematic view of the state of forming decreased diameter regions (concave regions) in the neck in the process of forming the neck after forming a narrowingly tapered portion in carrying out an embodiment of the method for growing the silicon single crystal according to the present invention.

In the process of forming the neck after forming the narrowingly tapered portion, a seed crystal is inserted into the surface layer of the silicon melt, and a single crystal is grown on the lower end of the seed crystal and, on that occasion, a narrowingly tapered portion 8 is formed by decreasing the diameter of the seed crystal 7 and then a neck 9 is formed, as shown in FIG. 4. According to the method for growing single crystal of the present invention, the neck diameter ‘d’ of the neck 9 is decreased to ‘d1’ and then increased to form a decreased neck diameter region (concave region) 9b-1 in the stage of forming the neck 9. In this example, a total of four decreased neck diameter regions from 9b-1 to 9b-4 are formed in the same manner.

In addition to forming the decreased diameter regions, the increased diameter regions may be formed. For example, a convex region 9a-1 between the decreased diameter regions 9b-1 and 9b-2 as shown in FIG. 4 is an increased diameter region. Thus, this is an example in which the diameter ‘d’ of the neck 9 is once decreased to ‘d1’ and then the increased diameter region 9a-1 is formed. In this case, three increased diameter regions are formed.

The reason of forming the increased diameter regions or decreased diameter regions by increasing or decreasing the neck diameter in this way in the process of forming the neck after forming the narrowingly tapered portion is because dislocations remaining in the central axial region of the neck (on-axis dislocations) can be eliminated thereby. Particularly even when the neck cannot be made small enough in diameter and so the diameter thereof is considerably large in case of the silicon single crystal of large diameter and heavy weight, on-axis dislocations can be reliably eliminated.

The range of increase or decrease in neck diameter when increasing or decreasing the diameter is preferably within 1 mm. When the pulling up of a silicon single crystal with a diameter of 300 mm is taken as an example, because usually the neck diameter is decreased to form a neck with a diameter of 4 mm to 6 mm using a silicon seed crystal with a diameter of not less than 10 mm, it is recommended that the neck diameter after increasing or decreasing the same by at most 1 mm should fall within the range of 4 mm to 6 mm.

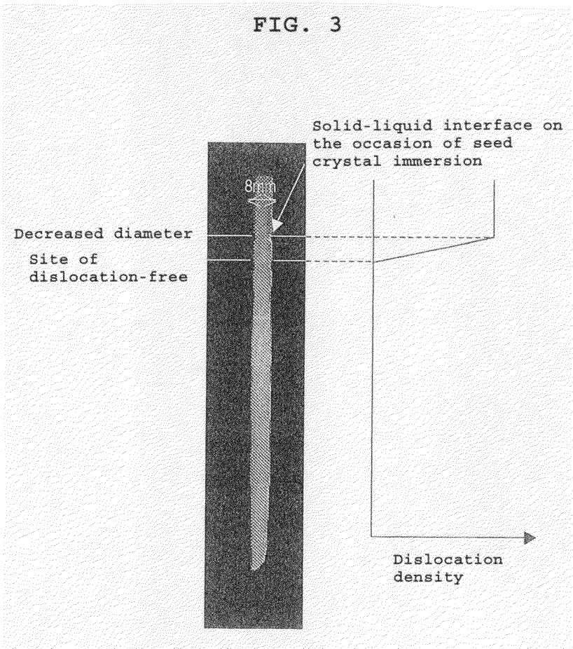

The number of increased diameter regions thus formed or decreased diameter regions thus formed(namely the number of sites where relevant regions are formed) is not particularly specified. While four decreased diameter regions are formed in the example shown in FIG. 4, forming only one decreased diameter region can completely eliminate dislocations as shown in FIG. 3.

The increased diameter region or decreased diameter region may be formed by varying the silicon single crystal pull rate. The increased diameter region or decreased diameter region can be formed with ease by slightly decreasing or increasing the pull rate.

The reason why dislocations remaining in the central axial region of the neck (on-axis dislocations) can be eliminated by increasing or decreasing the neck diameter in the process of neck formation is thought to be as follows. Namely, the frequent change of shape of the solid-liquid interface (melt/crystal interface on the occasion of phase transformation from the silicon melt to a crystal) by changing the silicon single crystal pull rate causes changes in a travelling direction of dislocations which should remain in the central axial region of the neck and should hardly move toward the periphery of the neck, resulting in discharging such dislocations toward the periphery. Dislocations are completely eliminated accordingly.

It is more effective to change the pull rate frequently within a narrow range rather than changing it gradually. From the viewpoint of changes in shape of the solid-liquid interface, the increase and decrease in neck diameter can be regarded as equivalent to each other, hence effects of the same nature can be produced. Since, however, decreasing the neck diameter is generally of advantage in eliminating dislocations, it is preferable to decrease the neck diameter.

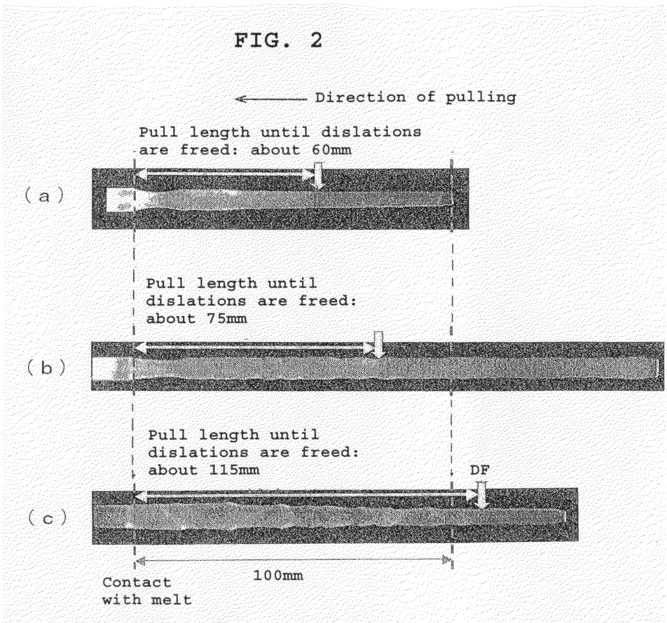

The above-cited Japanese Patent No. 2822904 describes that the range of fluctuation in diameter of a generally cylindrical narrowed portion should be kept within 1 mm, and FIG. 2 of the publication schematically shows concaves and convexes resulting from such fluctuations. However, the increased diameter regions (convex regions) or the decreased diameter regions (concave regions) to be formed in the neck in an embodiment of the present invention are distinctly different from the concaves and the convexes generated in the generally cylindrical narrowed portion as described in the Japanese Patent No. 2822904.

Namely, the purpose of forming the convex or concave regions in the neck in an embodiment of the present invention is to cause the frequent change in shape of the solid-liquid interface in the process of forming the convex or concave regions by forcedly changing the silicon single crystal pull rate as described above, and thereby eliminating dislocations remaining in the central axial region of the neck (on-axis dislocations). And forming the convex or concave regions has such effect. To the contrary, concaves and convexes generated in the generally cylindrical narrowed portion as described in Japanese Patent No. 2822904 are controlled so that these concaves and convexes (namely variations in generally cylindrical narrowed portion diameter as caused by disturbances such as melt temperature fluctuations and melt convection fluctuation) become as small as possible to moderate stress concentration on these concaves and convexes, and prevent the generation of plastic deformation to enhance the strength.

In a more preferable embodiment of the method for growing a silicon single crystal according to the present invention, if the above neck diameter is increased or decreased at the final stage in the process of forming the neck, all dislocations including on-axis dislocations can be eliminated more efficiently. When the neck diameter is increased or decreased in a condition that such dislocations are present in the neck at a high density, the dislocations may be bred contrarily. Skilled persons can judge from the observation of the shape of the seams (crystal habit lines) on the neck outside surface whether the dislocations other than those existing in the central axial region are eliminated during forming the neck.

FIG. 5 is a view showing the process of forming a neck portion (narrowingly tapered portion and neck) to be carried out in an embodiment of the method for growing a silicon single crystal according to the present invention in step order. As shown in the figure, the step of “formation of an increased diameter region(s) or a decreased diameter region(s)” is immediately followed by the step of “shoulder formation”, and the diagram shows the process of forming the neck portion in the above-mentioned more preferable embodiment.

In the method for growing a silicon single crystal according to the present invention, if a plurality of the increased diameter regions or decreased diameter regions are formed, it is very effective in enhancing the dislocation eliminating effect. The neck 9 shown in FIG. 4 as explained above is an example and four decreased diameter regions are formed (at 4 sites) therein.

In the method for growing a single crystal according to the present invention, the purpose of forming an increased diameter region or decreased diameter region in the neck is to intentionally change the silicon single crystal pull rate so as to vary the shape of the solid-liquid interface as mentioned above, and thereby to change the travelling direction of on-axis dislocations, which otherwise should hardly move toward the periphery of the neck, toward the periphery. And the frequent variations in shape of solid-liquid interface by forming a plurality of increased diameter regions or decreased diameter regions can provide a plenty of opportunities to change the travelling direction of dislocations. The formation of increased diameter regions or decreased diameter regions (namely change of pull rate) is preferably performed successively without pause as shown in FIG. 4 to cause the change in shape of solid-liquid interface frequently,.

The number of increased diameter regions or decreased diameter regions to be formed in the neck may be properly determined according to the conditions for growing the single crystal to be pulled. For example, when the neck diameter must be made large or when a silicon single crystal having [110] as its crystallographic axis is grown, it is recommended that the number of forming increased diameter regions or decreased diameter regions be increased. This is because the crystal structure of the silicon single crystal having [110] as its crystallographic axis involves (111) plane serving as a slip plane parallel to the direction of the pulling axis, and dislocations generated upon contacting with the silicon melt hardly free out of a seed crystal even subjected to seed narrowing and often remain in the central axial region of the neck.

According to the method for growing a silicon single crystal of the present invention and the embodiment thereof, even when the silicon single crystal is heavy and large in diameter, and so the diameter of the narrowingly tapered portion cannot be made small enough during seed narrowing, dislocations remaining in the central axial region of the neck (on-axis dislocations) can be reliably eliminated in a simple and easy manner. Therefore, the silicon single crystal absolutely free of dislocations including on-axis dislocations can be grown.

As described hereinabove, the method for growing a silicon single crystal according to the present invention comprises: forming a narrowingly tapered portion; and then providing increased or decreased neck diameter regions in the process of forming the neck, when growing a single crystal by CZ method. According to this growing method, dislocations remaining in the central axial region of the neck can be reliably eliminated and an absolutely dislocation-free silicon single crystal can be grown even when the diameter of the neck portion cannot be made sufficiently small.

Therefore, the method for growing silicon single crystal according to the present invention can be widely utilized in the field of semiconductor substrate material manufacture.

1. A method for growing a silicon single crystal by the Czochralski method, namely by feeding silicon materials for crystal into a crucible to melt the materials to obtain a melt, and pulling up a seed crystal immersed into the melt while rotating the seed crystal to thereby grow a silicon single crystal on the lower end of the seed crystal, comprising:
forming a narrowingly tapered portion with a gradually decreased seed crystal diameter by pulling up the seed crystal inserted in the melt; and
providing an increased neck diameter region or a decreased neck diameter region in the process of forming a neck with a constant nominal diameter in such a manner that the increased neck diameter region is provided by increasing the neck diameter, followed by decreasing the diameter, or alternatively, the decreased neck diameter region is provided by decreasing the neck diameter, followed by increasing the diameter.

2. The method for growing a silicon single crystal as claimed in claim 1, wherein the increased neck diameter region or the decreased neck diameter region is provided at the final stage in the process of forming the neck.

3. The method for growing a silicon single crystal as claimed in claim 1, wherein a plurality of the increased diameter regions or decreased diameter regions are provided.

4. The method for growing a silicon single crystal as claimed in claim 1, wherein the silicon single crystal to be pulled-up has [110] as its crystallographic axis.

5. The method for growing a silicon single crystal as claimed in claim 2, wherein the silicon single crystal to be pulled-up has [110] as its crystallographic axis.

6. The method for growing a silicon single crystal as claimed in claim 3, wherein the silicon single crystal to be pulled-up has [110] as its crystallographic axis.
